(19) United States
(12) Patent Application Publication
(10) Pub. No.: US 2007/0161133 A1
(43) Pub. Date: Jul. 12, 2007

(54) Method for implanting carbon nanotube

(75) Inventors: Shih-Chieh Liao, Taichung City (TW); Hui-Ta Chen, Taichung City (TW)

Correspondence Address: BRUCE H. TROXELL, 5205 LEESBURG PIKE, SUITE 1404, FALLS CHURCH, VA, 22041, US

(73) Assignee: Industrial Technology Research Institute

(21) Appl. No.: 11/580,295

(22) Filed: Oct. 13, 2006

(30) Foreign Application Priority Data
Dec. 22, 2005 (TW) 094145786
Sep. 19, 2006 (TW) 095134525

(51) Int. Cl. H01L 21/428; H01L 21/00

(52) U.S. Cl. 438/20; 977/742; 977/842; 438/795

(57) ABSTRACT

The present invention relates to a method of implanting carbon nanotube (CNT), which is especially being adopted for forming CNTs in carbon nanotube field emitting displays (CNT-FEDs). The method comprises steps of: transferring a medium by an electromagnetic wave generating means for forming a media layer of adhesive and conductive ability; and exposing a CNT material to the electromagnetic wave generating means for implanting CNTs in a plurality of gate apertures by the light pressure of the electromagnetic wave generating means. By the aforesaid method, the problems troubling conventional CNT formation methods, such as the density of CNT formed thereby is not sufficient, the adhesion of the substrate used thereby is low, and the CNT formation requires to be performed under a high temperature ambient, etc., can be solved.

### FIELD OF THE INVENTION

The present invention relates to a method of implanting carbon nanotubes, and more particularly to an implanting method that utilizes the electromagnetic wave.

### BACKGROUND OF THE INVENTION

With the high quality of image keeping breast of the cathode ray tube, and advantages of thin and less power consumption, the carbon nanotube field emission display, also called CNT-FED, gradually becomes more competitive to the other displaying technologies, such as LCD display, and PDP display.

Because carbon nanotubes have characteristics of low conducting electric field, high density emission electric current, and high stability, the CNT-FED which is capable to be large, flat and less expensive display, has lower driving voltage, faster reacting speed, larger range of the operating temperature, higher emitting efficiency, wider viewing angle, and less power consumption than the LCD and PDP.

The coating techniques of nanotubes disclosed in the prior arts can be divided into three major methods, one is screen printing, another is electrophoretic deposition and the other is chemical vapor deposition. Each method of the prior art has its own drawback, for example, homogeneity is difficult to be controlled in screen printing, poor adhesion and difficulty for mass production are the drawbacks of electrophoretic deposition and the chemical vapor deposition is operated in the high temperature that the glass substrate can't withstand.

In summation to the description above, it is required to provide the method of implanting carbon nanotube so as to overcome the shortcomings of the prior art.

### SUMMARY OF THE INVENTION

The primary objective of the present invention is to provide a method of carbon nanotubes implantation, which utilities the electromagnetic wave to form a media layer with adhesive and conductive characteristics and to implant the carbon nanotubes on the media layer to generate a carbon nanotube field emission source having strong adhesion and even density so that the purpose of making large area CNT-FED and repairing the defects of CNT-FED are capable of being practiced.

For the purpose to practice the foregoing objective, a method for implanting carbon nanotubes is provided, which comprises the steps of: firstly, coating a media material on a bearing plate; then, utilizing an electromagnetic wave to force the media material to adhere to the surface of a substrate while enabling the media material adhered on the substrate to form a media layer; next, coating a layer of a carbon nanotube material having a plurality of carbon nanotubes on the bearing plate; and finally, implanting the carbon nanotubes, coated on the bearing plate, on the media layer through an electromagnetic wave.

In a preferred aspect, the electromagnetic wave is substantially a laser, such as a full band laser, or an ultra violet wave.

In a preferred aspect, the carbon nanotube material is the mixture of a polymer and the plurality of carbon nanotubes, wherein the polymer is a material of fluidity that each molecule of the molecular bond thereof is capable of adhering a carbon nanotube independently.

In a preferred aspect, the method of coating is spin coating.

In a preferred aspect, the media material is substantially a material having adhesive and conductive ability, wherein the media material is silver paste.

In a preferred aspect, a focusing unit comprising a lens and a mask is disposed between the electromagnetic wave and the bearing plate.

In a preferred aspect, a beam splitting unit is disposed between the electromagnetic wave and the bearing plate.

For the purpose to practice the foregoing objective, the present invention further provides a method for implanting carbon nanotubes, which comprises the steps of: firstly, providing a substrate structure with a plurality of gate apertures; then, coating a media material on a bearing plate; thereafter, utilizing an electromagnetic wave to force the media material to adhere to the surface of a substrate while enabling the media material adhered on the substrate to form a media layer; after that, coating a layer of a carbon nanotube material having a plurality of carbon nanotubes on the bearing plate; and finally, implanting the carbon nanotubes, coated on the bearing plate, on the media layer through an electromagnetic wave.

In a preferred aspect, the substrate structure further comprises: a cathode plate, and a gate structure. The gate structure includes a insulating layer formed on the cathode plate and a gating layer formed on the insulating layer, wherein each gate aperture is channeling through the insulating layer and the gating layer to contact with the cathode plate.

For achieving the foregoing objective, the present invention further provides a method for implanting carbon nanotubes comprising the steps of: firstly, providing a substrate structure with a plurality of gate apertures, while embedding a CNT field emission source in each gate aperture; then, removing the CNT field emission source having defects; afterwards, coating a media material on a bearing plate; next, utilizing an electromagnetic wave to force the media material to adhere to the surface of a substrate while enabling the media material adhered on the substrate to form a media layer; after that, coating a layer of a carbon nanotube material having a plurality of carbon nanotubes on the bearing plate; and finally, implanting the carbon nanotubes, coated on the bearing plate, on the media layer through an electromagnetic wave.

In a preferred aspect, the method to remove defects of carbon nanotubes is to utilize the electromagnetic wave which is preferably to be a laser, such as a full band laser or an ultra violet wave.

Other aspects and advantages of the present invention will become apparent from the following detailed description, taken in conjunction with the accompanying drawings, illustrating by way of example the principles of the present invention.

### BRIEF DESCRIPTION OF THE DRAWINGS

The drawings, incorporated into and form a part of the disclosure, illustrate the embodiments and method related to this invention and will assist in explaining the detail of the invention.

FIG. 1 is a flow chart illustrating the preferred embodiment according to the present invention of a method for implanting carbon nanotube.

FIG. 2A to FIG. 2E are schematic flow illustrating the preferred embodiment of making CNT field emission display according to the method of the present invention.

FIG. 2F is a schematic of illustration depicting another embodiment of the step of forming carbon nanotube material on the bearing plate.

FIG. 3A to FIG. 3F are schematic flow illustrating the preferred embodiment of clearing and repairing the defects of CNT field emission display according to the method of the present invention.

### DESCRIPTION OF THE PREFERRED EMBODIMENT

For your esteemed members of reviewing committee to further understand and recognize the fulfilled processing flow and manufacturing characteristics of the invention, several preferable embodiments cooperating with detailed description are presented as the follows.

The primary objective of the present invention is to form the adhesive material on a specific position and implant the carbon nanotubes on the adhesive material through the electromagnetic wave, wherein the electromagnetic wave is selected to be an ultra violet wave, a laser, or others substantially like the same. The laser is adopted to be the embodiment of the electromagnetic wave in the following disclosures; however, it should not to be construed as limiting.

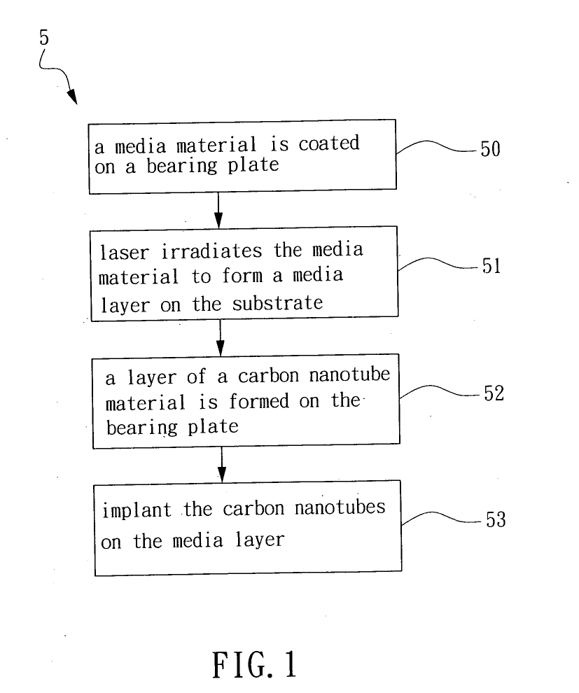

Referring to FIG. 1, which is a flowchart illustrating the preferred embodiment according to the present invention of a method for implanting carbon nanotubes. The method 5 comprising the steps of: firstly, as illustrated in step 50, a media material is coated on a bearing plate through spin coating. Next, as illustrated in step 51, the radiation pressure generated from the laser exerts forces on the media material coated on the bearing plate so as to make the media material adhere to the surface of a substrate to form a media layer, wherein the media material is selected to be a material with characteristics of conductivity and adhesion, such as silver paste or others alternatively like the same and the substrate is a cathode plate.

After that, as illustrated in step 52, a layer of a carbon nanotube material having a plurality of carbon nanotubes is formed on the bearing plate by method of spin coating. The carbon nanotube material is a mixture of a polymer with fluidity, and the plurality of carbon nanotubes. With higher flowing capability of the polymer and phenomenon of self-assemble, each molecule of the molecular bond thereof is capable of adhering a carbon nanotube independently through the attraction force between function groups of the molecular. The polymer is substantially a polyaniline. Besides, the carbon nanotube material can alternatively be a mixture of a alcohol and the plurality of carbon nanotubes.

Finally, as illustrated in step 53, the laser is utilized to make the carbon nanotubes, coated on the bearing plate, to be adhered on the media layer. When the laser irradiate the carbon nanotubes, the photons impacting the carbon nanotubes will generate a radiation pressure to exert forces on the carbon nanotubes, formed on the bearing plate, so as to implant the carbon nanotubes on: the media layer. The laser described foregoing is capable to be a full band laser. The implanting area is affected by the irradiating area of the laser or electromagnetic wave. For the purpose to generate smaller pixels or partial implanting, it is preferred to disposed a focusing unit comprising a lens and a mask between the laser (or electromagnetic wave) and the bearing plate so that a irradiating area is capable of being controlled.

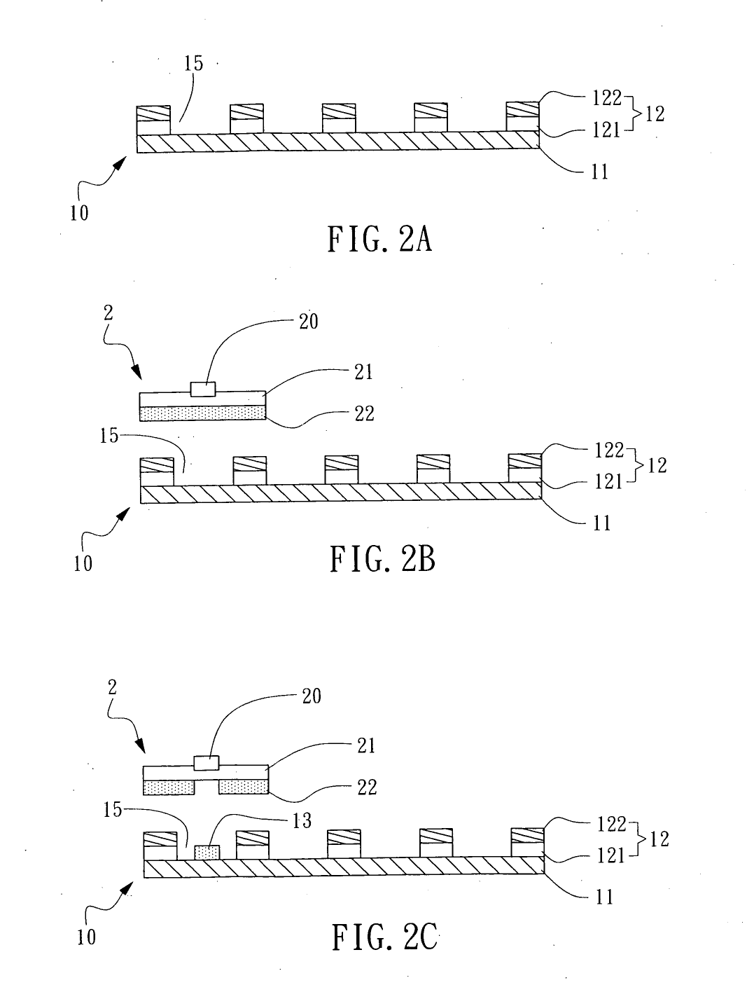

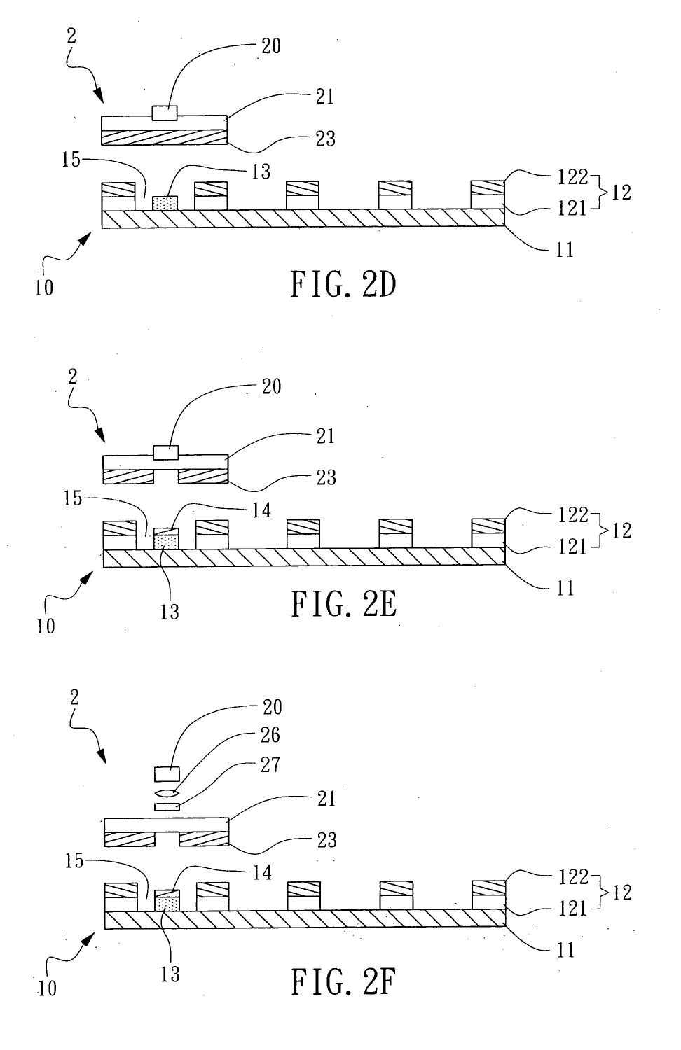

The method disclosed in the present invention is capable of being adopted in the field of CNT-FED manufacturing and defects clearing and repairing for defective carbon nanotube field emission source in CNT-FED during manufacturing. Please refer to FIG. 2A to FIG. 2E, which are schematic flows illustrating the preferred embodiment of making CNT field emission display according to the method of the present invention. At first, as illustrated in FIG. 2A, a substrate structure 10 with a plurality of gate apertures 15 is provided. The substrate structure 10 comprises a cathode plate 11, and a gate structure 12. The gate structure 12 includes a insulating layer 121, formed on the cathode plate 11, and a gating layer 122, formed on the insulating layer 121, wherein the gate apertures 15 are formed on the cathode plate 11 channeling through the insulating layer 121 and gating layer 122. The method to form the gate structure 12 is a prior art that are well practiced, so it will not be described in detail herein.

After FIG. 2A, the process illustrated in FIG. 2B is going on, a laser apparatus 2 is provided, which comprises a laser unit 20 and a bearing plate 21. A media material 22 is coated on the bearing plate 21 through spin coating, and then the laser apparatus 2 is located to the position corresponding to the gate aperture 15. Thereafter, referring to FIG. 2C, laser lights emitted from the laser unit 20 irradiate the media material 22, coated on the bearing plate 21, so as to make the media material 22 adhere to the cathode plate 11 in the gate aperture 15 to form a media layer 13. The media material 22 is selected to be a material with characteristics of conductivity and adhesion, such as silver paste or alternatively like the same. In this step, the wavelength of the laser is 1064 nm and energy density is 28 mJ/cm² and the width of laser pulse is 10 ns.

Next, as illustrated in FIG. 2D, a layer of a carbon nanotube material 23 having a plurality of carbon nanotubes is coated on the bearing plate 21, wherein the carbon nanotube material 23 is a mixture of a polymer and the plurality of carbon nanotubes. By means of higher flowing capability of the polymer, each molecule of the molecular bond thereof is capable of adhering a carbon nanotube independently. Finally, the illustration depicted in FIG. 2E, laser lights emitted from the laser unit 20 generate radiation pressure that exerts forces on the carbon nanotube material 23 formed on the bearing plate 21 so as to implant the carbon nanotubes on the media layer 13 to form a CNT field emitted layer 14. The implanting area of the carbon nanotubes is affected by the irradiating area of the laser or electromagnetic wave. As shown in FIG. 2F, for the purpose to generate smaller pixels or partial implanting, it is preferred to dispose a focusing unit comprising a lens 26 and a mask 27 between the laser unit 20 (or electromagnetic wave) and the bearing plate 21 so that an irradiating area is capable of being controlled. The foregoing laser unit is substantially a full band laser. Repeating the flows illustrated from FIG. 2A to FIG. 2E, any kind of size of display area of CNT-FEDs are capable of being manufactured. In addition, for the purpose of increasing the throughput of the manufacturing process, it is preferred to arrange a beam splitting unit to split the laser light emitted from the laser unit 20 into a plurality of beams so as to process toward a plurality of gate apertures 15 simultaneously.

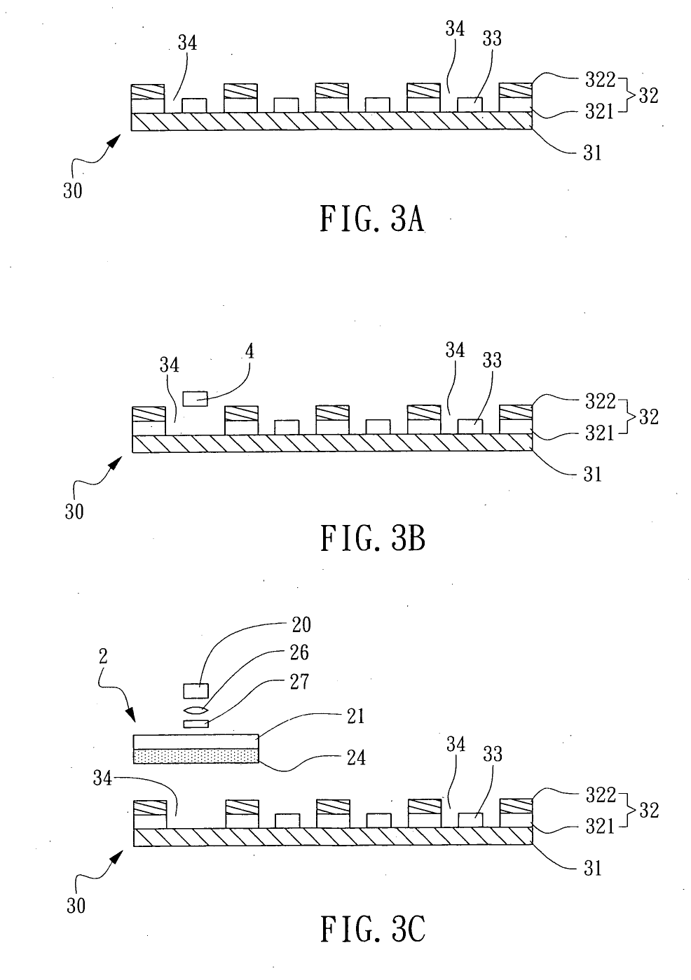

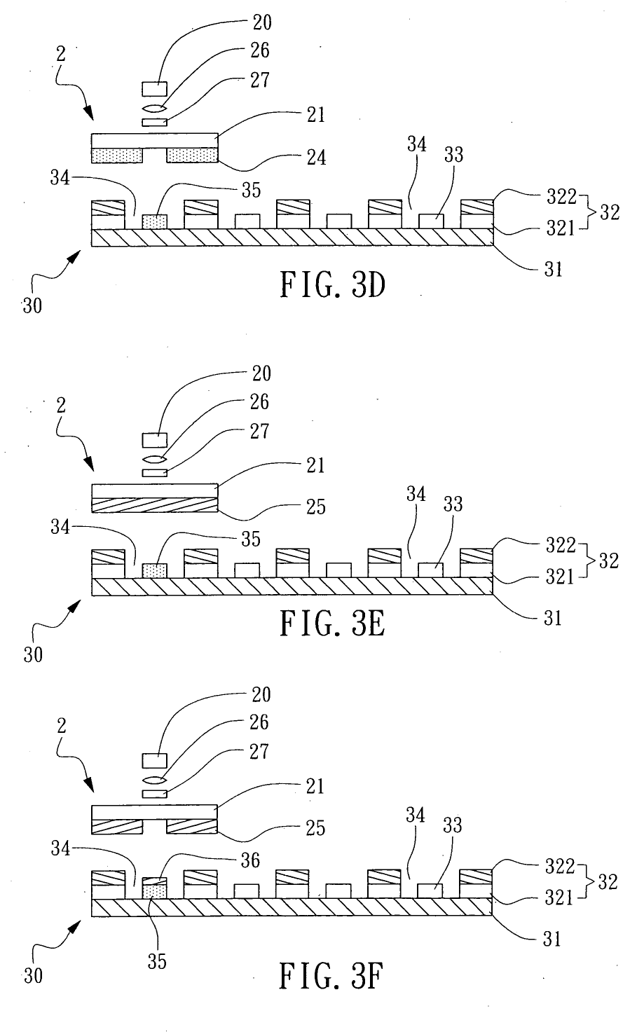

In the following, another embodiment illustrated in FIG. 3A to FIG. 3F according to the method of the present invention is disclosed, which is a method for clearing and repairing the defects of carbon nanotubes inspected in the CNT-FED. As illustrated in FIG. 3A, a substrate structure 30 with a plurality of gate apertures 34, inside each of which a CNT field emission source 33 is disposed.

The substrate structure 30 comprises a cathode plate 31, and a gate structure 32 that includes a insulating layer 321, formed on the cathode plate 31, and a gating layer 322, formed on the insulating layer 321, wherein the gate apertures 34 are formed on the cathode plate 31 channeling through the insulating layer 321 and gating layer 322. The CNT field emission source 33 is formed in the method of prior arts, which are the coating techniques of carbon nanotubes, such as screen-printing, electrophoretic deposition and chemical vapor deposition. The defects are generated easily during the process forming the CNT field emission source through those prior arts, and those defects are also difficult to be cleaned and repaired; however, by means the steps disclosed in the following, defects cleaning and repairing are becoming efficient and effective.

When defects are detected by the inspection equipments, the step illustrated in FIG. 3B is proceeded, which the electromagnetic generating means 4 is utilized to remove the CNT field emission sources 33 having defects, wherein the electromagnetic generating means is a laser, an ultra violet wave or others substantially like the same. After that, as shown in FIG. 3C, a laser apparatus 2 is provided, which comprises a laser unit 20 and a bearing plate 21. In this embodiment, a focusing unit comprising a lens 26 and a mask 27 between the laser unit 20 (or electromagnetic wave) and the bearing plate 21 so that an irradiating area is capable of being controlled. A media material 24 is coated on the bearing plate 21 through spin coating, and then the laser apparatus 2 is located to the position corresponding to the gate aperture 34. The media material 24 is selected to be a material with characteristics of conductivity and adhesion, such as silver paste or alternatively like the same. Thereafter, continuing to FIG. 3D, laser lights emitted from the laser unit 20 generate radiation pressure that exert forces on the media material 24, coated on the bearing plate 21, which makes the media material 24 adhere to the cathode plate 31 in the gate aperture 34 to form a media layer 35. In this step, the wavelength of the laser is 1064 nm and energy density is 28 mJ/cm² and the width of laser pulse is 10 ns.

After that, as illustrated in FIG. 3E, a layer of a carbon nanotube material 25 having a plurality of carbon nanotubes is coated on the bearing plate 21, wherein the carbon nanotube material 25 is a mixture of a polymer and the plurality of carbon nanotubes. By means of higher flowing capability of the polymer, each molecule of the molecular bond thereof is capable of adhering a carbon nanotube independently. Finally, referring to FIG. 3F, laser lights emitted from the laser unit 20 exert forces on the plurality of carbon nanotubes formed on the bearing plate 21 so as to implant the carbon nanotubes on the media layer 35 to form a CNT field emitted layer 36. After the flows from FIG. 3A to FIG. 3F, the defects are capable of being repaired. In this embodiment, the laser unit is substantially a full band laser.

By the aforesaid disclosed embodiments, the problems troubling conventional. CNT FED formation methods, such as the density of CNT formed thereby is not sufficient, the adhesion of the substrate used thereby is low, and the CNT formation requires to be performed under a high temperature ambient, etc., can be solved. While the present invention has been described and illustrated herein with reference to the preferred embodiment thereof, it will be understood by those skilled in the art that various changes in form and details may be made therein without departing from the spirit and the scope of the invention.

What is claimed is:

1. A method for implanting carbon nanotubes, comprising the steps of:
coating a media material on a bearing plate;
utilizing an electromagnetic wave to force the media material to adhere to the surface of a substrate while enabling the media material adhered on the substrate to form a media layer;
coating a layer of a carbon nanotube material having a plurality of carbon nanotubes on the bearing plate; and
implanting the carbon nanotubes, coated on the bearing plate, on the media layer through an electromagnetic wave.

2. The method according to the claim 1, wherein the electromagnetic wave is selected from a group consisting of a full band laser and an ultra violet wave.

3. The method according to the claim 1, wherein the carbon nanotube material is the mixture of a polymer and the plurality of carbon nanotubes.

4. The method according to the claim 3, wherein the polymer is substantially a polyaniline.

5. The method according to the claim 1, wherein the media material is substantially a material having adhesive and conductive ability.

6. The method according to the claim 5, wherein the media material is silver paste.

7. The method according to the claim 1, wherein the carbon nanotube material is the mixture of an alcohol and the plurality of carbon nanotubes.

8. The method according to the claim 1, wherein a focusing unit comprising a lens and a mask is disposed between the electromagnetic wave and the bearing plate.

9. The method according to the claim 1, wherein a beam splitting unit is disposed between the electromagnetic wave and the bearing plate.

10. A method for implanting carbon nanotubes, comprising the steps of:
providing a substrate structure with a plurality of gate apertures;
coating a media material on a bearing plate;
utilizing an electromagnetic wave to force the media material to adhere to the surface of a substrate while enabling the media material adhered on the substrate to form a media layer;
coating a layer of a carbon nanotube material having a plurality of carbon nanotubes on the bearing plate; and
implanting the carbon nanotubes, coated on the bearing plate, on the media layer through an electromagnetic wave.

11. The method according to the claim 10, wherein the substrate structure further comprises:
a cathode plate; and
a gate structure, including a insulating layer formed on the cathode plate and a gating layer formed on the insulating layer;
wherein each gate aperture is channeling through the insulating layer and the gating layer to contact with the cathode plate.

12. The method according to the claim 10, the carbon nanotube material is the mixture of a polymer and the plurality of carbon nanotubes.

13. The method according to the claim 12, wherein the polymer is substantially a polyaniline.

14. The method according to the claim 10, wherein the media material is substantially a material having adhesive and conductive ability.

15. The method according to the claim 14, wherein the media material is silver paste.

16. The method according to the claim 10, wherein the carbon nanotube material is the mixture of an alcohol and the plurality of carbon nanotubes.

17. The method according to the claim 10, wherein the electromagnetic wave is selected from a group consisting of a full band laser and an ultra violet wave.

18. The method according to the claim 10, wherein a focusing unit comprising a lens and a mask is disposed between the electromagnetic wave and the bearing plate.

19. The method according to the claim 10, wherein a beam splitting unit is disposed between the electromagnetic wave and the bearing plate.

20. A method for implanting carbon nanotubes, comprising the steps of:
providing a substrate structure with a plurality of gate apertures, while embedding a CNT field emission source in each gate aperture;
removing the CNT field emission source having defects;
coating a media material on a bearing plate;
utilizing an electromagnetic wave to force the media material to adhere to the surface of a substrate while enabling the media material adhered on the substrate to form a media layer;
coating a layer of a carbon nanotube material having a plurality of carbon nanotubes on the bearing plate; and
implanting the carbon nanotubes, coated on the bearing plate, on the media layer through an electromagnetic wave.

21. The method according to the claim 20, wherein the substrate structure further comprises:
a cathode plate; and
a gate structure, including a insulating layer formed on the cathode plate and a gating layer formed on the insulating layer;
wherein each gate aperture is channeling through the insulating layer and the gating layer to contact with the cathode plate.

22. The method according to the claim 20, the carbon nanotube material is the mixture of a polymer and the plurality of carbon nanotubes.

23. The method according to the claim 22, wherein the polymer is substantially a polyaniline.

24. The method according to the claim 20, wherein the carbon nanotube material is the mixture of an alcohol and the plurality of carbon nanotubes.

25. The method according to the claim 20, wherein the media material is substantially a material having adhesive and conductive ability.

26. The method according to the claim 25, wherein the media material is silver paste.

27. The method according to the claim 20, wherein the electromagnetic wave is selected from a group consisting of a full band laser and an ultra violet wave.

28. The method according to the claim 20, wherein the method for removing the CNT field emission source having defects is to utilize an electromagnetic wave.

29. The method according to the claim 20, wherein a focusing unit comprising a lens and a mask is disposed between the electromagnetic wave and the bearing plate.

30. The method according to the claim 20, wherein a beam splitting unit is disposed between the electromagnetic wave and the bearing plate.
